(19) United States
(12) Patent Application Publication
(10) Pub. No.: US 2011/0225818 A1
(43) Pub. Date: Sep. 22, 2011

(54) METHOD OF MANUFACTURING AN LED ILLUMINATOR DEVICE

(76) Inventors: Shih-Bin Chiu, Tainan City (TW); Yan-Hua Chen, Tainan City (TW); Yi-Ching Chuang, Liuying Township (TW)

(21) Appl. No.: 12/727,613

(22) Filed: Mar. 19, 2010

(51) Int. Cl. H05K 3/30

(52) U.S. Cl. 29/832

(57) ABSTRACT

A method of manufacturing an LED illuminator is provided. At least one flat heat pipe (FHP) is provided, on which a flat surface is formed. A treating tool is provided to fix the FHP. A printed circuit layer is formed on the flat surface, which includes an insulated layer, a conductive layer and a solder mask layer spread on the flat heat pipe in order, to form solder portions. After that, solder paste is applied on the solder portions, and LED elements are disposed on the solder portions correspondingly. Finally, the FHP and the LED elements are passed through a reflow oven, to accomplish an LED illuminator. The FHP further has locating holes, which are used for orientating the FHP and connecting a heat-dissipating module by a concise assembling element.

### BACKGROUND OF THE INVENTION

1. Field of the Invention

The present invention relates to a method of manufacturing an LED illuminator, in particular, to a method for directly soldering light emitting diodes on a flat heat pipe.

2. Description of Related Art

Light emitting diode; LED, has advantages such as small size, impact-endurable, long lifespan, low power consumption, cold illumination and mercury-free . . . etc. It has become the major item of research and developing recently. In the beginning is indication light, and now is LED light product. The development trend of LED is from low power to high power, and the application aspects are diversified more and more.

With the wide application of high power LED, the requirement of heat dissipation is raised gradually. If that heat is not radiated well, there will be many problems, such as the light efficiency is lowered, lifespan is shortened, light quality is changed . . . etc. Therefore, the arrangement of thermal-conduction needs an efficient heat-dissipating structure to radiate heat outside the illuminator module to avoid the aforementioned problems.

The current heat-dissipating way of LED illuminators are mostly heat sinks for increasing the thermal-conductive area. The disadvantages are lower heat-dissipating efficiency and larger occupied space. Some prior arts use a heat pipe coordinated with the heat sink to increase the heat-dissipating efficiency, however the cost is higher.

Moreover, all the aforementioned heat-dissipation ways have the common disadvantage, in which the heat of LED elements is necessarily radiated through a printed board. The printed board is a low thermal conductive material, so that the heat produced by LED elements can not be radiated efficiently and quickly to the heat pipe. To improve the high thermal resistance of the printed board, metal core PCB (MCPCB) of prior art is developed. However, the heat produced by the LED elements still need be radiated through the multi-layers of the MCPCB and thermal grease (or thermal paste) and then to the heat pipe.

Furthermore, a retention kit of complex structure is usually used to fix the LED elements to heat pipe and heat sink. The retention kit not only increases cost but also occupies space. Besides, to assemble the retention kit consumes manpower considerably.

Accordingly, in view of the aforesaid shortcomings, the present inventor not only to improve the assembly way of LED elements and heat pipe to increase thermal conductive efficiency, but also to use a concise structure for combining the heat pipe and heat sink to accomplish an LED illuminator.

### SUMMARY OF THE INVENTION

In view of the aforementioned issues, the present invention provides a method of manufacturing an LED illuminator, in which a printed circuit layer is formed on a flat heat pipe, so that LED elements can be soldered directly on the flat heat pipe. Thereby, the thermal-conductive path between the LED elements and the flat heat pipe is shortened to enhance the effectiveness of heat-dissipating.

Besides, the other aspect to be solved by the present invention is to provide a method of manufacturing an LED illuminator, which a treating tool is provided to form the printed circuit layer on a plurality of flat heat pipe simultaneously, so that it can save manufacturing time and cost.

Furthermore, the present invention is to provide a method of manufacturing an LED illuminator including a concise mechanism to fix a heat-dissipating module on the flat heat pipe, for accomplishing the LED illuminator. A conventional retention kit is omitted therefore, manufacturing cost is saved, and the occupied space is reduced.

To achieve the aforementioned objectives, the present invention provides a method of manufacturing an LED illuminator, including steps as follows. First, at least one flat heat pipe is provided and a flat surface is formed thereon. Next, a treating tool is provided to fix the at least one flat heat pipe. Then, a printed circuit layer is formed on the at least one flat heat pipe. The process to form the printed circuit layer includes as follows. First, an insulated layer is applied on the flat surface of the at least one flat heat pipe. Next, a conductive layer is applied on the insulated layer to form a plurality of conducted circuits. Then, a solder-resistant layer is applied on the conductive layer to form a plurality of solder portions. After the printed circuit layer is formed, solder paste is applied on the solder portions, and a plurality of LED elements are disposed on the solder portions of the flat heat pipe. Finally, the flat heat pipe and the LED elements are passed through a reflow oven.

To achieve the aforementioned objectives, the present invention further provides a printing halftone-screen which is able to cover the flat heat pipes.

To achieve the aforementioned objectives, the treating tool, which is provided according to the method of manufacturing an LED illuminator of the present invention, includes a plurality of fixing rods. The flat heat pipe is formed with a plurality of locating holes corresponds with the fixing rods. Besides, the present invention further includes steps as follows. First, at least one heat-dissipating module is provided, in which the heat-dissipating module is formed with a plurality of assembling holes. Next, a plurality of assembling elements is provided, and the assembling elements pass through the assembling holes of the heat-dissipating module and the locating holes of the flat heat pipe. Thereby, the heat-dissipating module is fixed on the flat heat pipe.

The advantages resulted from the present invention are as follows.
1. The present invention directly forms the printed circuit layer on the flat heat pipe to solder the LED elements on the printed circuit layer, so that the thermal conductive path between the LED elements and the flat heat pipe is shortened to enhance the heat-dissipating efficiency.
2. The present invention based on the aforementioned method, further provides a printing halftone-screen which be able to cover the at least one flat heat pipe, and uses the same one of the treating tool to simultaneously form the printed circuit layer on the flat heat pipes. Therefore, manufacturing time and cost are saved.
3. The present invention utilities the locating holes formed on the flat heat pipe, which provide not only orientation function when forming the printed circuit layer, but also use concise assembling elements to combine the flat heat pipe and the heat-dissipating module. An LED illuminator is accomplished therefore. The convention retention kit is omitted, so that manufacturing cost is saved and occupied space is reduced.

In order to further understand the techniques, means and effects the present invention takes for achieving the prescribed objectives, the following detailed descriptions and appended drawings are hereby referred, such that, through which, the purposes, features and aspects of the present invention can be thoroughly and concretely appreciated; however, the appended drawings are merely provided for reference and illustration, without any intention to be used for limiting the present invention.

### BRIEF DESCRIPTION OF THE DRAWINGS

FIG. 1 is a side view of showing a method of manufacturing an LED illuminator according to the present invention;

FIG. 2 is a perspective view of a flat heat pipe with a printed circuit layer according to the present invention;

FIG. 3 is a exploded perspective view of an LED illuminator according to the present invention;

FIG. 4 is an enlarged cross-sectional view along line 44 in FIG. 3;

FIG. 5 is an enlarged cross-sectional view of locating holes of another embodiment according to the present invention; and

FIG. 6 is a perspective view of the LED illuminator of second embodiment according to the present invention.

### DETAILED DESCRIPTION OF THE PREFERRED EMBODIMENTS

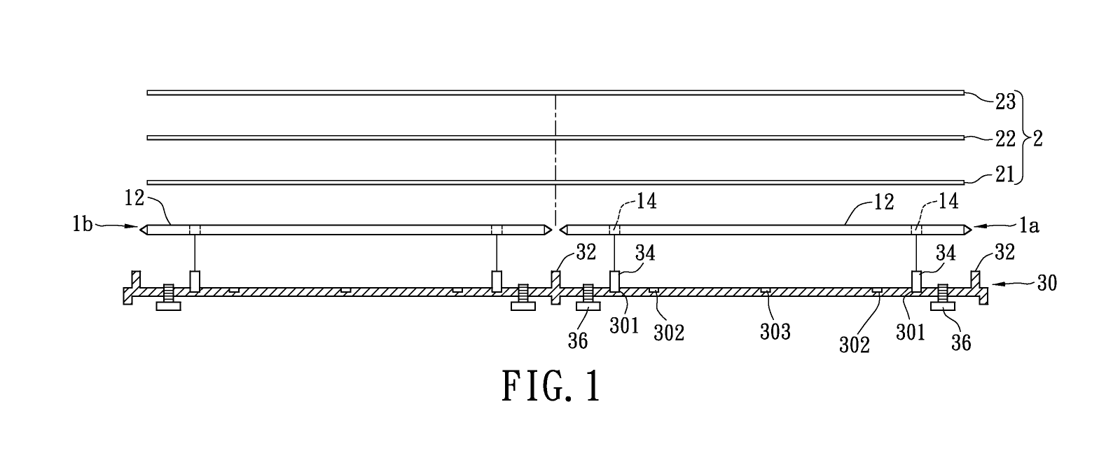

Referring now to FIG. 1, a side view of showing a method of manufacturing an LED illuminator according to the present invention is shown. The present invention provides a method of manufacturing an LED illuminator, which includes steps as follows. First, at least one flat heat pipes is provided. In this embodiment, two flat heat pipes 1a and 1b are provided, on which a flat surface 12 is formed respectively. The flat heat pipes 1a and 1b preferably are rectangular board shaped. In this embodiment, since the flat heat pipe 1a and the flat heat pipe 1b are symmetrical, so that hereafter the flat heat pipe 1a is interpreted representatively.

The process to form the flat surface 12 on the flat heat pipes 1a and 1b includes as follows. First, a surface of the flat heat pipes 1a and 1b are polished, and then to clean particles (not shown) which are produced by the polishing step of forming the flat surface 12. The flat surface 12 is used to directly form a printed circuit layer 2 on the flat heat pipes 1a, 1b.

Before the printed circuit layer 2 is formed, a treating tool 30 is provided by the present invention to retain the flat heat pipes 1a and 1b. Thus, the flat heat pipes 1a and 1b could be retained on the treating tool 30. The treating tool 30 has a plurality of orientating protrusions 32 to orientate the flat heat pipes 1a, 1b. The orientating protrusions 32 are against edges of the flat heat pipes 1a and 1b.

Since each of the flat heat pipes may has different size, a second retaining way is provided according to the present invention. The treating tool 30 has a plurality of fixing rods 34. The flat heat pipes 1a and 1b are formed with a plurality of locating holes 14, which are corresponded with the fixing rods 34. The locating holes 14 could be schemed out their locations according to the printed circuit layer 2 in advance, and pass through the flat heat pipe 1a. The locating holes 14 could be treated as orientating marks on the printing halftone-screen on one aspect, and to fix the heat-dissipating module on the other hand, which will be described after.

The fixing rods 34 of the treating tool 30 preferably are movable. For example, the treating tool 30 is formed with a plurality of orientating blind-holes 301, 302, 303. The fixing rods 34 could be inserted in the orientating blind-holes 301, or moved in the orientating blind-holes 302, 303. The orientating blind-holes 301, 302, 303 could be arranged in an array on the treating tool 30. Therefore, when locations of the locating holes 14 are changed according to different requirements of the flat heat pipes 1a and 1b, the fixing rods 34 of the present invention could be moved accordingly.

One characteristic of the present invention is that the printed circuit layer 2 can be once formed on the flat heat pipes 1a and 1b through the treating tool 30, so that manufacturing time can be saved. When the present invention adapts the way of screen printing, the area of one printing halftone-screen is several-folds of the flat heat pipe. Through one of the printing halftone-screen, it can work on several ones of the flat heat pipes. Therefore, the manpower can be saved. In this embodiment, only two flat heat pipes 1a, 1b are illustrated in view side. The present invention reasonably could provide the treating tool with a matched size according to the area of the printing halftone-screen. Thus several flat heat pipes can be simultaneously formed with the printed circuit layer 2.

The flat heat pipes maybe have different thickness. To print uniformly on each of the flat heat pipes when printing, the treating tool 30 further includes at least one of the level-adjusted devices 36. The level-adjusted device 36 pass through the treating tool 30 and upward against a bottom surface of the flat heat pipes 1a, 1b to adjust the top surface of the flat heat pipe 1a, 1b on the same level. In this embodiment, the level-adjusted device 36 in a simplest way is a bolt. The user can adjust the level-disposition of the level-adjusted device 36 under the treating tool 30, and the top surfaces of the flat heat pipes 1a, 1b could be adjusted to the same level.

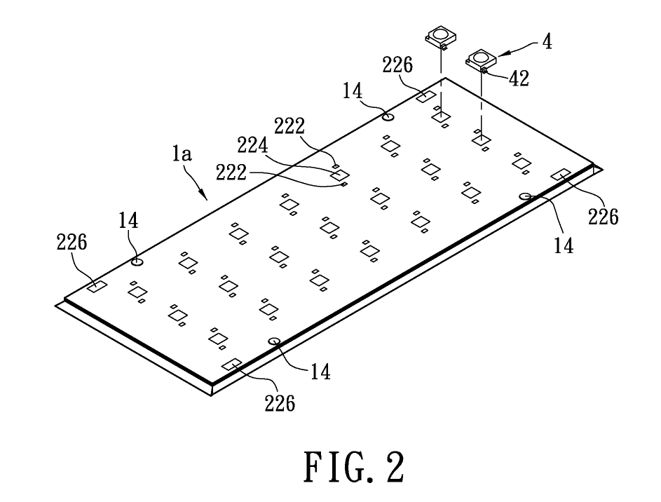

There is another characteristic in the present invention, which the printed circuit layer 2 is formed directly on the flat surface 12 of the flat heat pipes 1a, 1b. The electronic elements on the printed circuit layer 2, such as LED elements, did not need to radiate heat through any printed board. Therefore, thermal conductive path is shortened and heat-dissipating efficiency is enhanced. The process to form the printed circuit layer 2 is described thereinafter. Since the flat heat pipes 1a and 1b are conductive metallic pieces, an insulated layer 21 is formed firstly on the flat surface 12 of the flat heat pipes 1a, 1b. Next, a conductive layer 22 is formed on the insulated layer 21 to form a plurality of conducted circuits (not shown). Finally, a solder-resistant layer 23 is formed on the conductive layer 22, so that some required portions of the conductive layer 22 could be exposed outside to form a plurality of exposed areas. The exposed areas can be treated as, for example, solder portions 222 to solder leads, or solder portions 226 to connect wires, or exposed portion 224 to contact a bottom of LED elements 4 directly to radiate heat conveniently (as shown in FIG. 2).

The insulated layer 21 preferably is made of insulated material of low thermal resistance, and heat-conductive. For example, UV-curable resin, epoxy resin of well thermal conduction, or epoxy resin plus glass fabric, or adhesive epoxy glass fiber cloth of well thermal conduction. The conductive layer 22 could be conductive paste, such as copper paste, silver paste, silver-aluminum paste, aluminum paste, or expansive metal paste. The advantage is able to use screen printing. Alternatively, the print circuits of the conductive layer 22 could be copper tinsel formed by etching to bear a higher current. The solder-resistant layer 23 is formed by applying solder mask, which can protect parts of the conducted circuits, to avoid a short circuit between closed circuits caused by flowing solder paste when soldering electronic elements. It also can isolate the flat heat pipes 1a, 1b from reacting oxidation with moisture in air. After the solder mask is applied, it could further be treated with an anti-oxidant surface to enhance anti-oxidant ability according to requirements. According to the aforementioned way, at least the solder-resistant layer 23 could be formed by screen printing.

Referring to FIG. 2, in which a perspective view of a flat heat pipe with a printed circuit layer according to the present invention is illustrated. An instance is described according to the flat heat pipe 1a. Following the step of applying the printed circuit layer 2, solder paste (not shown) is applied on the solder portions 222. Then, a plurality of the LED elements 4 is disposed on the solder portions 222 of the flat heat pipe 1a correspondingly. Finally, let the flat heat pipe 1a and the LED elements 4 to pass through a reflow oven (not shown), so that leads 42 of the LED elements 4 are soldered on the flat heat pipe 1a. Accordingly, an LED illuminator of the present invention is accomplished. The solder portions 226 can be soldered with wires 24 to connect electricity power.

The present invention after tested, the thermal conductive efficiency of the flat heat pipe is effected few by high-temperature of the reflow oven. Alternatively, to reduce the effectiveness of high-temperature of the reflow oven onto the flat heat pipe, the present invention can seal one end of the flat heat pipe and form an opening at the other end of the flat heat pipe. And, then to process the steps of forming the printed circuit layer 2. After the steps of forming the solder-resistant layer 23, filling a working liquid into the flat heat pipe through the opening, such as water, methanol, and acetone. Finally, sealing the opening of the flat heat pipe. Besides, the present invention can seal the opening temporarily by tape . . . etc. to avoid particles entering the flat heat pipe. The opening is opened before filling the working liquid.

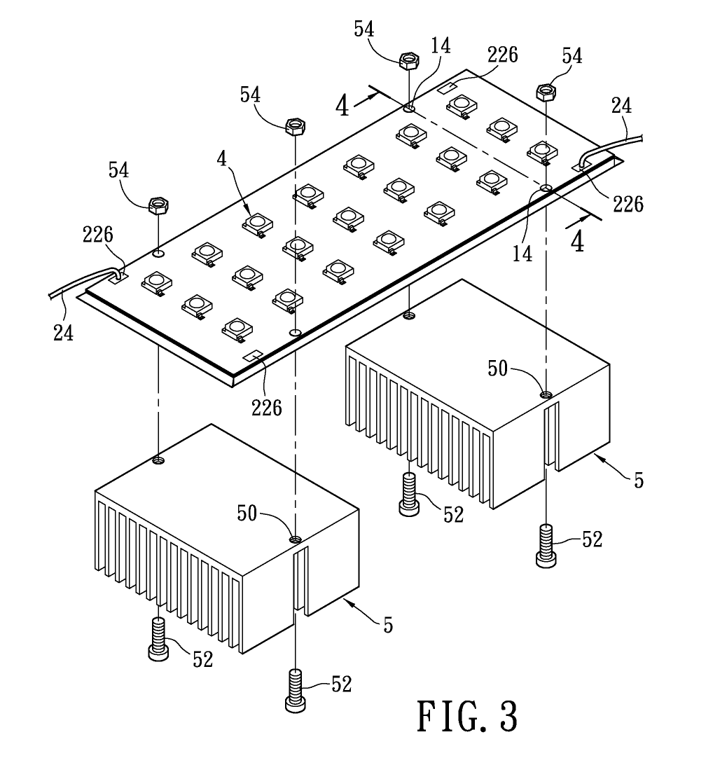

Referring to FIG. 3, in which an exploded perspective view of an LED illuminator according to the present invention is illustrated. The present invention further provides a pair of heat-dissipating modules 5 on two sides of the bottom of the flat heat pipe 1a to enhance heat-dissipating efficiency. Each of the heat-dissipating modules 5 has a plurality of assembling holes 50. The assembling elements could be bolts 52 and nuts 54 in FIG. 3, or rivet, soldering, thermosetting polymers material . . . etc., which are used to pass though the assembling holes 50 of the heat-dissipating module 5 and the locating holes 14 of the flat heat pipe 1a. Therefore, the heat-dissipating module 5 is fixed on the flat heat pipe 1a. The locating holes 14 of the flat heat pipe 1a not only can be used to retain the printed circuit layer 2 in a previous stage, but also can be used to fix the heat-dissipating module 5 in a later assembly stage.

The present invention utilizes the assembling elements of concise structure, so that the heat-dissipating module 5 can be firmly combined with the flat heat pipe 1a without any retention kit. The manufacturing cost can be reduced, space occupied is less, and manpower of assembling the retention kit is skipped. The aforementioned construction for radiating heat could be extended with much more heat-dissipating elements, such as heat sink, fans, water-cooling module, even other flat heat pipe . . . etc.

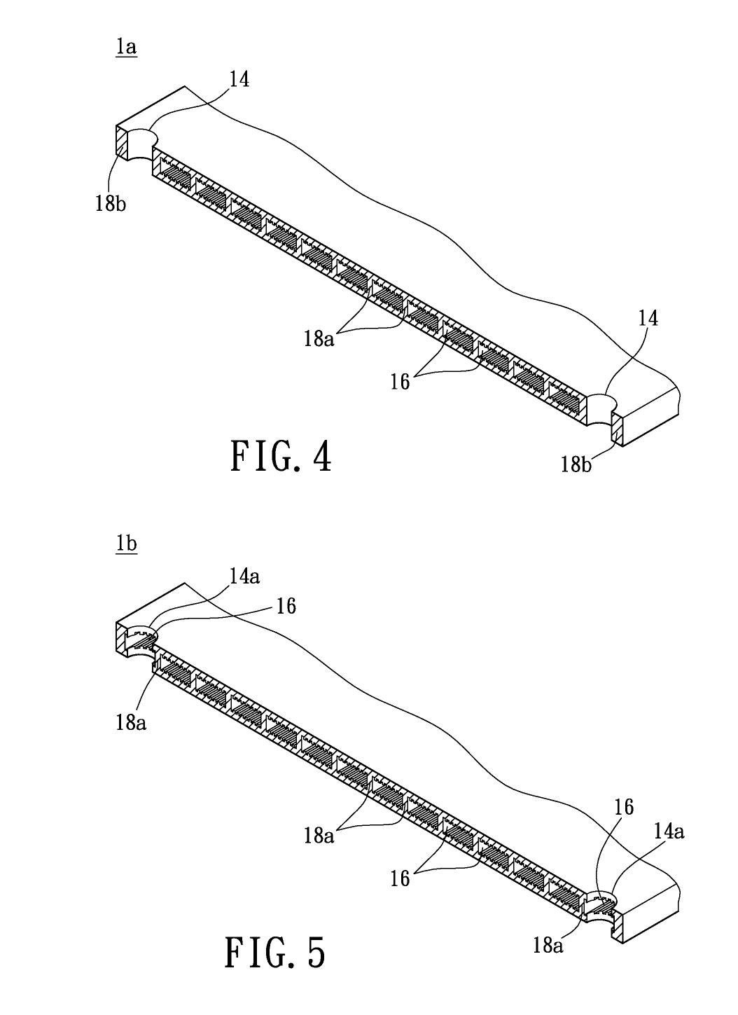

Referring to FIG. 4, in which an enlarged cross-sectional view along line 44 in FIG. 3 is illustrated. The flat heat pipe 1a in the present invention is a rectangular shaped board, in which a plurality of channels is provided preferably. The advantages of flat heat pipe are, the volume of working fluid is increased and the capillary force is higher, working fluid of liquid/vapor phases are dispersed, and friction force between liquid/vapor phases is reduced. The material of flat heat pipe could be copper, aluminum, magnesium-alloy metal. The internal micro structure could be hollow channels, grooves, sintering, powder . . . etc. In this embodiment, the flat heat pipe 1a has a plurality of partitions 18a, 18b formed therein and a plurality of liquid channels 16 formed between the partitions 18a, 18b. The locating holes 14 of the flat heat pipe 1a pass through the partitions 18b which has a width larger that a diameter of the locating holes 14. The partitions 18b can be designed in advance before the flat heat pipe is manufactured. For example, the way of aluminum extruding is adapted to manufacture the flat heat pipe, the partitions 18b would be reserved with a thicker width.

Referring to FIG. 5, in which an enlarged cross-sectional view of locating holes of another embodiment according to the present invention is illustrated. In this embodiment, the flat heat pipe 1b is formed with a pair of locating holes 14a which pass through the liquid channel 16. Because the flat heat pipe of the present invention is multi-channels designed, the locating holes 14a are located together in one or two channels and there are still many channels functioned well. The present invention is experimented and illustrated after to proof this embodiment still has a rather heat-dissipating ability.

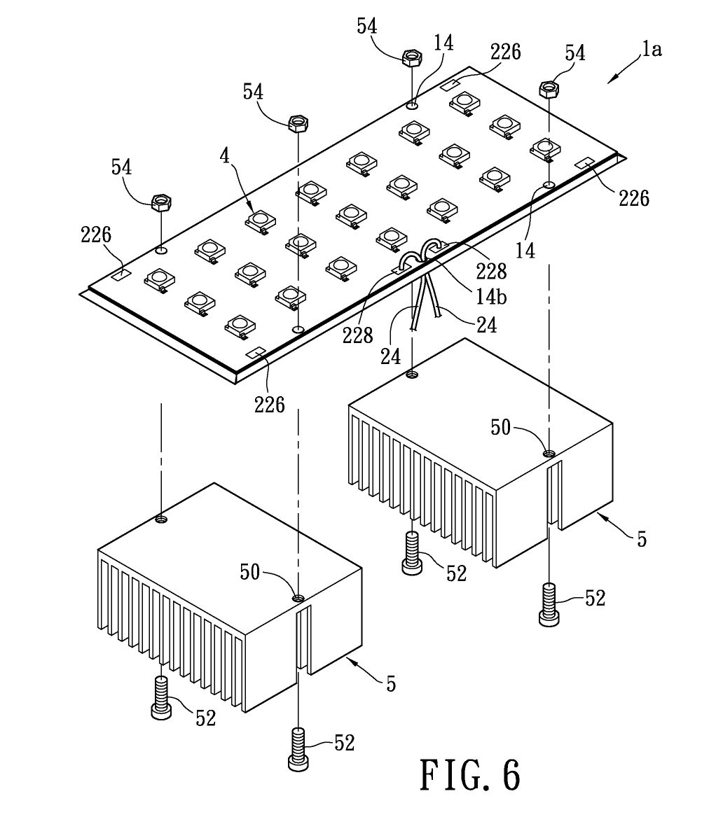

Referring to FIG. 6, in which a perspective view of the LED illuminator of second embodiment according to the present invention is illustrated. According to the aforementioned construction of the present invention, the locating holes have difference functions. For example, a space between the pair of heat-dissipating modules 5 could be used. The present invention could provide another one of the locating hole 14b passing through the flat heat pipe 1a and is between the pair of heat-dissipating modules 5. Two solder portions 228 are formed adjacent to the locating holes 14b, so that the wires 24 solders on the solder portions 228 can pass through the locating holes 14b and extend to the space between the pair of heat-dissipating modules 5. Thus space is more compact.

Referring to table 1 as follows, an LED illuminator according to the present invention has a contrastive data sheet with five groups of experiment. The five groups of experiment are temperatures measured the seven LEDS along a row line in FIG. 3, LED1, LED2, LED3, LED4, LEDS, LED6, and LED7 from left to right. Each group experimental conditions are as follows, (hereafter wherein the heat-dissipating module is called “FIN”, the locating holes are called “hole”, four locating holes in FIG. 3 and four ones in FIG. 5 are used to experiment. Besides, the heat-transferring medium between the flat heat pipe and the heat-dissipating module is called “medium”)

Group 1: FIN, None; medium, none; hole, none.

Group 2: FIN, 1; medium, thermal paste; hole, none.

Group 3: FIN, 1; medium, thermal grease; hole, Yes.

Group 4: FIN, 2; medium, thermal paste; hole, none.

Group 5: FIN, 2; medium, thermal grease; hole, Yes.

TABLE 1
Experiment data sheet of 5 GRS. (□)

| | GR. 1 | GR. 2 | GR. 3 | GR. 4 | GR. 5 |
|---|---|---|---|---|---|
| LED1 | 67.86 | 64.18 | 61.23 | 57.46 | 55.22 |
| LED2 | 66.15 | 61.11 | 60.99 | 55.22 | 54.20 |
| LED3 | 67.29 | 61.70 | 58.81 | 57.58 | 56.22 |
| LED4 | 66.72 | 60.87 | 60.14 | 55.59 | 54.20 |
| LED5 | 67.29 | 61.46 | 61.58 | 56.22 | 54.71 |
| LED6 | 67.75 | 61.58 | 55.97 | 56.22 | 54.96 |
| LED7 | 66.38 | 60.39 | 58.69 | 55.09 | 53.82 |

To contrast Groups 2 and 3, Group 3 means the LED illuminator of the present invention having four locating holes drilled, and one of the heat-dissipating module 5 with the flat heat pipe 1b through bolts, nuts and thermal grease. Comparing with Group 2, which has no locating hole and thermal paste used to combine one heat-dissipating module 5, Group 3 has a higher heat-dissipating efficiency.

To contrast Groups 4 and 5, Group 5 means the LED illuminator of the present invention having four locating holes, and one pair of the heat-dissipating modules 5 combined with the flat heat pipe 1b through bolt, nut and thermal grease. Comparing with Group 4, which has no locating holes and thermal paste is used to combine one pair of the heat-dissipating module 5, Group 5 has a higher heat-dissipating efficiency.

It is proved by the experiments that, the LED illuminator of the present invention even is drilled with four locating holes, however it has better heat-dissipating results through the concise mechanism of the assembling elements (bolt 52 and nut 54 as shown in FIG. 3) in which thermal grease is applied therein.

The method of manufacturing an LED illuminator according to the present invention includes characteristics and function as follows.

1. The present invention directly forms the printed circuit layer 2 on the flat heat pipe 1a, 1b, and the LED elements 4 are soldered on the flat heat pipe 1a directly, so that the thermal-conductive path between the LED element 4 and the flat heat pipe 1a is shortened to enhance heat-dissipating efficiency.

2. The present invention utilizes one printing halftone-screen which is able to cover the flat heat pipes 1a, 1b, and one piece of the treating tool 30 can simultaneously form the printed circuit layer 2 on a plurality of flat heat pipes 1a, 1b. Therefore, manufacturing time and cost is reduced.

3. The flat heat pipe 1a of the present invention is formed with the locating holes 14, which not only providing a retaining function when the printed circuit layer 2 is forming, but also providing a concise structure to combine the flat heat pipe 1a with the heat-dissipating module 5 through the assembling elements, such as bolt 52 and nut 54. The LED illuminator could be accomplished accordingly, and conventional retention kit is omitted. Therefore, manufacturing cost can be saved, and occupied space is reduced.

The above-mentioned descriptions represent merely the preferred embodiment of the present invention, without any intention to limit the scope of the present invention thereto. Various equivalent changes, alternations or modifications based on the claims of present invention are all consequently viewed as being embraced by the scope of the present invention.

What is claimed is:

1. A method of manufacturing an LED illuminator, comprising steps as follows:
providing at least one flat heat pipe, and forming a flat surface on the at least one flat heat pipe;
providing a treating tool to fix the at least one flat heat pipe;
forming an insulated layer on the flat surface of the at least one flat heat pipe;
forming a conductive layer on the insulated layer to define a plurality conducted circuits thereon;
forming a solder-resistant layer on the conductive layer to define a plurality of solder portions;
applying solder paste on the solder portions;
disposing a plurality of LED elements on the solder portions on the flat heat pipe; and
passing the flat heat pipe and the LED elements through a reflow oven.

2. The method of manufacturing an LED illuminator as claimed in claim 1, wherein the step of forming the flat surface on the flat heat pipe comprising:
polishing a surface of the flat heat pipe; and
cleaning particles produced by the polishing step to form the flat surface.

3. The method of manufacturing an LED illuminator as claimed in claim 1, further comprising a step of providing a printing halftone-screen to cover the at least one flat heat pipe, thereby printing the insulated layer, the conductive layer, and the solder-resistant layer on the flat heat pipe.

4. The method of manufacturing an LED illuminator as claimed in claim 3, wherein the insulated layer is made of low thermal resistance, thermal conductive, insulated material.

5. The method of manufacturing an LED illuminator as claimed in claim 3, wherein the conductive layer is made of conductive mortar.

6. The method of manufacturing an LED illuminator as claimed in claim 3, wherein the conductive layer is copper tinsel.

7. The method of manufacturing an LED illuminator as claimed in claim 1, wherein the treating tool has a plurality of orientating protrusions for orientating the at least one flat heat pipe, the orientating protrusions are against edges of the at least one flat heat pipe.

8. The method of manufacturing an LED illuminator as claimed in claim 1, wherein the treating tool has a plurality of fixing rods, the flat heat pipe is formed with a plurality of locating holes corresponding to the fixing rods.

9. The method of manufacturing an LED illuminator as claimed in claim 8, wherein the treating tool concaved with a plurality of orientating blind-holes on a top surface thereof, and the fixing rods are inserted in the orientating blind-holes.

10. The method of manufacturing an LED illuminator as claimed in claim 9, wherein the orientating blind-holes are arranged in an array on the treating tool.

11. The method of manufacturing an LED illuminator as claimed in claim 1, wherein the treating tool has a plurality of level-adjusted devices on a bottom thereof, the level-adjusted devices pass through the treating tool and upward against a bottom surface of the at least one flat heat pipe, thereby top surfaces of the at least one flat heat pipe are adjustable to be located on one lever.

12. The method of manufacturing an LED illuminator as claimed in claim 8, wherein the at least one flat heat pipe is rectangular board shaped, and has a plurality of partitions formed therein and a plurality of liquid channels formed between twp of the partitions; wherein the locating holes of the flat heat pipe pass through the partitions, a width of the partitions is larger that a diameter of the locating holes.

13. The method of manufacturing an LED illuminator as claimed in claim 12, wherein the locating holes pass through the liquid channel.

14. The method of manufacturing an LED illuminator as claimed in claim 8, further comprising steps as follows:
providing at least one heat-dissipating module, the heat-dissipating module is formed with a plurality of assembling holes; and
providing a plurality of assembling elements, the assembling elements pass through the assembling holes of the heat-dissipating module and the locating holes of the flat heat pipe; thereby the heat-dissipating module is fixed on the flat heat pipe.

15. The method of manufacturing an LED illuminator as claimed in claim 14, further comprising steps as follows:
providing a pair of the heat-dissipating modules disposed two sides of a bottom of the flat heat pipe and define a space;
forming a locating hole passed through the flat heat pipe and between the pair of heat-dissipating modules; and
forming two solder portions adjacent to the locating holes;
thereby wires soldered on the solder portions pass through the locating hole between the pair of heat-dissipating module and are received between the pair of heat-dissipating modules.

16. The method of manufacturing an LED illuminator as claimed in claim 1, further comprising steps as follows:
sealing one end of the at least one flat heat pipe before providing the treating tool, and forming an opening at the other end of the at least one flat heat pipe;
filling a working liquid into the flat heat pipe through the opening, after forming the solder-resistant layer; and
sealing the opening of the flat heat pipe.

17. The method of manufacturing an LED illuminator as claimed in claim 16, further comprising steps as follows:
sealing the opening temporarily, after sealing one end of the flat heat pipe and forming the opening.
